(19) United States
(12) Patent Application Publication
(10) Pub. No.: US 2010/0294546 A1
(43) Pub. Date: Nov. 25, 2010

(54) CIRCUIT BOARD AND METHOD FOR A LOW PROFILE WIRE CONNECTION

(76) Inventors: Sean Nickel, Monroeville, PA (US); James Wahl, Pittsburgh, PA (US)

Correspondence Address: WOOD, HERRON & EVANS, LLP, 2700 CAREW TOWER, 441 VINE STREET, CINCINNATI, OH, 45202, US

(21) Appl. No.: 12/470,676

(22) Filed: May 22, 2009

(51) Int. Cl. H05K 1/02; H05K 3/36

(52) U.S. Cl. 174/255; 29/830

(57) ABSTRACT

A printed circuit board includes a first layer including a groove formed therein. The groove extends between opposing face surfaces. A second layer is coupled with one face surface of the first layer. The second layer includes a through hole in communication with the groove of the first layer. A third layer is coupled to other face surface of the first layer opposite the second layer. Portions of the second and third layers cooperate with the groove and forming a cavity with an opening at the edge of the board. The cavity is accessible through the through hole of the second layer. A printed circuit board includes multiple layers which are coupled together. A wire is electronically coupled to the printed circuit board by being inserted into the cavity with solder applied via the through hole. An alternative embodiment utilizes two layers to define the board and cavity.

### FIELD OF THE INVENTION

The invention relates generally to circuit board technology, and particularly to a circuit board and method for facilitating a connection between an electrical conductor or wire and a circuit board.

### BACKGROUND OF THE INVENTION

Printed circuit boards (PCBS) are used in a wide variety of electronic applications in order to form the electronic circuits needed for devices to function. In many cases and applications, a printed circuit board may connect to remote electrical and electronic components through conductors, such as conductive wires. Different methods are known to accomplish the connection of such wires to a PCB, including through hole soldering, surface mount soldering, and the use of wire-to-board connectors. Various prior art methods is illustrated and discussed briefly below.

One method commonly used for board connection is through hole soldering. In this method, as illustrated in FIG. 1, the PCB 110 includes through holes 112. The through holes 112 are often plated with a conductive material 122, such as a metal layer or solder. For connection of a component (not shown) to board 110, the exposed ends 132a, 132b of connecting wires 130a, 130b associated with the component are passed into the holes 112. Solder 140 is then applied to contact the exposed ends 132a, 132b, and the material layer 122 and hold the wires 130a, 130b in place at a certain pitch P₁, as shown in FIG. 1.

Through hole soldering, as shown in FIG. 1, requires very little soldering expertise to assemble and complete. Furthermore, it results in a mechanically robust connection. However, because the wires 130a, 130b are inserted generally perpendicular to the plane of the board 110, the resulting finished board connection 100 has a relatively high profile h₁, although a somewhat shallow depth profile d₁ (See FIG. 7A). As shown in FIG. 7A, the resulting height h₁ will depend on the bend radius of the wire 130b. Additionally, the connection 100 can be very difficult to rework, requiring some soldering expertise to remove the wires 130a, 130b and the solder 140 without damaging the board 110 or electronic components thereon.

Another known connection method is surface mount soldering. As shown in FIGS. 2A-2B, connection 200 includes surface mount pads 212 positioned and placed on the PCB 210. The exposed ends 232a, 232b of the wires 230a, 230b are soldered directly to the pads 212, resulting in solder joints 242a, 242b. This is usually followed up with an encapsulant 220, as shown in FIG. 2B, that provides electrical insulation and strain relief to the solder joints 242a, 242b. While this method provides a very low height profile h₂ as shown in FIG. 7B, the risk of shorts usually forces a wider pitch P₂ for the wires 230a, 230b. The depth profile d₂ of the connection 200 on the PCB 210 is also increased over the connection of FIG. 7A because the depth d₂ must allow the encapsulant 220 to have sufficient PCB surface area to form a proper grip.

Due to the lack of mechanical isolation between the wires 230a, 230b, the surface mount soldering technique requires some assembly expertise to perform correctly. The quality of the solder joints 242a, 242b and the consistency and effectiveness of the encapsulant 220 are highly dependent on the operator that is performing the assembly operation. Since the encapsulant 220 is usually not easy to clean off, reworking this solution is particularly difficult. Despite the presence of the encapsulant 220, the robustness of this connection 200 is also relatively poor as the wires 230a, 230b are fairly vulnerable to pull force.

Another known method to connect wires to a PCB is to use a wire-to-board connector or set of connectors to hold the wires in the proper orientation to maintain contact, as shown in FIGS. 3A-3B. A connector system 300 uses mechanical crimps or connections (not shown) inside of a housing 324 to hold the ends of wires 330a, 330b in the housing. The housing then plugs into a receptacle 326, which is itself soldered to the PCB 310 using either a through hole or surface mount process. This connection method increases the complexity and cost of manufacturing. The tight control of the exposed ends of the wires 330a, 330b inside the housing 324, including the insulation of the non-exposed portions of the wires, results in a connection 300 with a fine pitch P₃. However, the additional pieces required to make a properly seized and stable receptacle 326 increase the size and cost of the overall footprint of the connector system 300 (h₃, d₃), as shown in FIG. 7C and further described below.

The connector system 300 using housing 324 and receptacle 326 is very easy to rework. Cable replacement is usually accomplished by pulling the housing 324 out of the receptacle 326 and replacing the housing with another housing wire harness. However, this solution is not mechanically robust. Also, the additional components provide additional failure points for contact contamination, cable breaking, and mechanical tolerances. Still further, there is a significant amount of cost required in the parts of the connector system 300.

Each of the above-described connection methods includes disadvantages which can make them unsuitable for certain applications. For example, in the case of wearable headsets, for example, a robust connection between the printed circuit board and the wires to other elements of the headset is important because of the high durability requirement of the product. Such a requirement is not met by the use of a surface mount solder connection or wire-to-board connector where the connection might easily break. Additionally, portability and shape are very important qualities of headsets, and so minimizing the height profile of each connection is of particular importance. That requirement is not met by use of a through hole solder connection, where the perpendicular connection carries a significant height profile.

As such, there is a need in the art to have a wire connection to a printed circuit board that is cost efficient, robust, easy to construct and maintain, and that has a low height profile.

### SUMMARY OF THE INVENTION

In one embodiment of the invention, a printed circuit board includes a first layer having a groove formed therein. The groove extends between opposing face surfaces. A second layer is coupled with one face surface of the first layer and includes a through hole in communication with the groove of the first layer. A third layer is coupled to other face surface of the first layer opposite the second layer and portions of the second and third layers cooperate with the groove and form a cavity with an opening at the edge of the board. The cavity is accessible through the through hole of the second layer.

In an exemplary method of fabricating a printed circuit board, a first layer includes a groove formed therein that extends between opposing face surfaces of the first layer. A second layer is coupled with one face surface of the first layer. The second layer includes a through hole formed therein. The second layer is positioned so that the through hole is in communication with the groove of the first layer. A third layer is coupled to the other face surface of the first layer opposite the second layer to form the printed circuit board. Portions of the second and third layers are positioned to cooperate with the groove and form a cavity with an opening at the edge of the board. The cavity is accessible through the through hole of the second layer.

### BRIEF DESCRIPTION OF THE DRAWINGS

The accompanying drawings, which are incorporated in and constitute a part of this specification, illustrate embodiments of the invention and, together with the detailed description of the embodiments given below, serve to explain the principles of the invention.

FIG. 1 is a perspective view of a through hole solder connection of two wires with a printed circuit board.

FIG. 2A is a perspective view of a surface mounted solder connection of two wires with a printed circuit board.

FIG. 2B is a perspective view that shows the circuit board connection of FIG. 2A with the addition of an encapsulant.

FIG. 3A is a perspective view of a printed circuit board including the receptacle for a wire-to-board connection.

FIG. 3B shows the receptacle of FIG. 3A with a wire connection housing inserted therein to form a wire-to-board connection.

FIG. 4 is a perspective view of three layers of printed circuit board according to one embodiment of the present invention.

FIG. 4A is a perspective view of another embodiment of the invention.

FIG. 5 is a perspective view of the three layers of FIG. 4 shown laminated into an exemplary printed circuit board.

FIG. 6 shows an exemplary circuit board assembly with wires coupled with the printed circuit board of FIG. 5 in accordance with aspects of the invention.

FIG. 7A is an elevational view of the connection of FIG. 1.

FIG. 7B is an elevational view of the connection of FIG. 2B.

FIG. 7C is an elevational view of the connection of FIG. 3B.

FIG. 7D is a cross sectional elevation view of the exemplary connection of FIG. 6 according to one embodiment of the invention.

FIG. 7E is a cross sectional elevation view of another embodiment of the invention.

FIG. 8 is an exploded view of layers of an exemplary circuit board of the invention.

FIG. 9 is a cross-sectional elevational view of a wire connection with a circuit board in accordance with aspects of the invention.

FIG. 10 shows an exemplary alternative circuit board assembly with wires coupled with the printed circuit board in accordance with aspects of the invention.

FIG. 11 is another embodiment of a circuit board assembly in accordance with aspects of the invention.

### DETAILED DESCRIPTION

Because many wire connections involve two physically proximate conductor or wires that need to be kept electrically separate (i.e., the distance between the two wires, or pitch, is a relevant factor), the examples herein will present a pair of wires connected to a PCB. However, the principles applied herein are also relevant for connecting a single wire to a PCB or connecting any plurality of wires to a PCB.

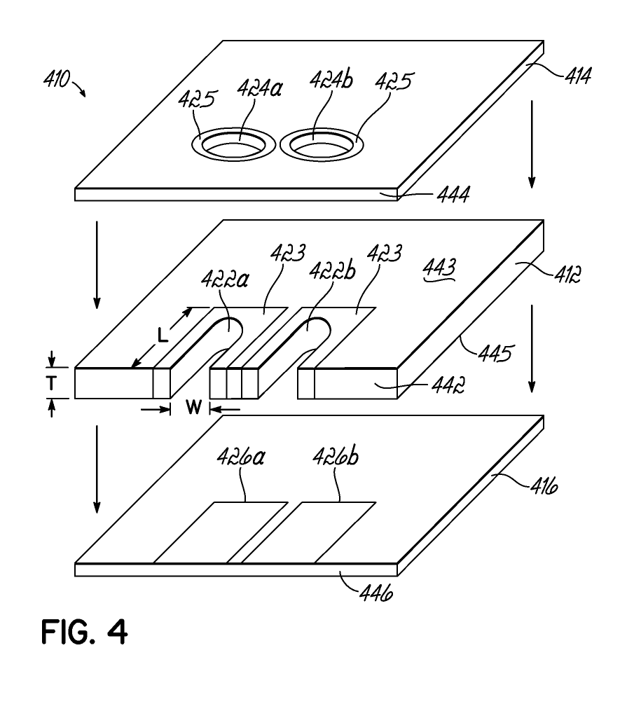

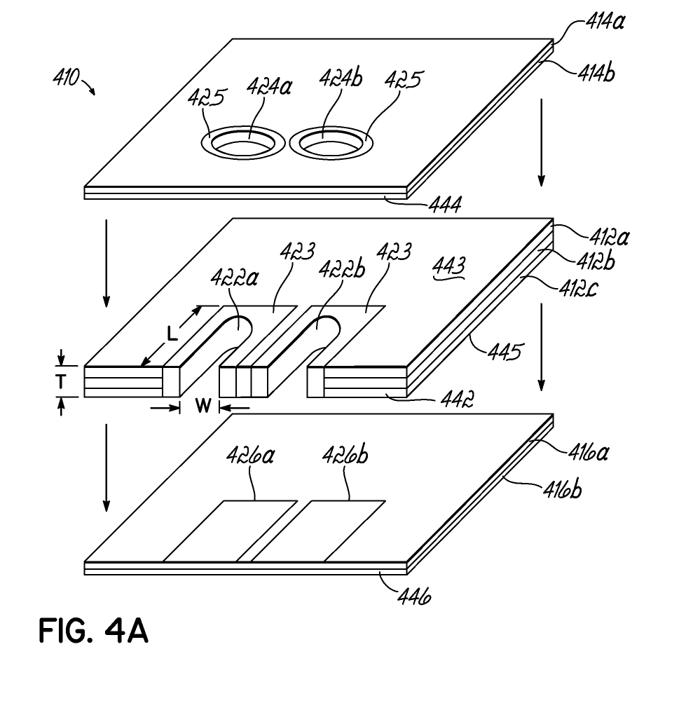

FIG. 4 shows one embodiment of a circuit board created with three separate PCB layers 412, 414, 416. A core layer 412 is positioned between upper layer 414 and lower layer 416.

Although terms such as upper and lower are utilized to describe an embodiment of the invention, it would be readily understood by a person of ordinary skill in the art that such terms are generally relative. For example, if the board is flipped upside down, the designation of an upper layer and lower layer is reversed.

As shown, a core layer 412 or first layer includes one or more grooves, and in the illustrated case, two grooves 422a, 422b that are formed and positioned along an edge 442 of board 412. The grooves are formed in the board 412 to extend between opposing face surfaces 443, and 445. The grooves also open to edge 442. Such grooves or openings 422a and 422b might be formed, such as by cutting away a section of the board layer 412. Alternatively, the board layer 412 might be fabricated with the grooves formed therein. In the illustrated embodiments, a pair of grooves are shown, but obviously a greater or lesser number of grooves might be utilized depending upon the wires or conductors to be coupled to the printed circuit board 410. Grooves 422a, 422b are appropriately sized in both width W and length L to receive wires or other conductors (shown in FIG. 6).

An upper layer or second layer 414 includes two through holes 424a, 424b, and a lower layer or third layer 416 includes two exposed, conductive pads 426a, 426b. The through holes 424a and 424b are formed by removal of board material from layer 414, such as by precise drilling or machining. Alternatively, board layer 414 might be formed with the through holes already therein in the proper placement. The through holes might be coated with a metal layer 425 through those holes to provide desirable and proper flow of solder, as well as to provide possibly a suitable electrical connection in the printed circuit board. The pads 426a, 426b are appropriately formed, such as by the deposit of a thin metal layer onto PCB layer 416 in a suitable fashion, which would be known to a person of ordinary skill in the art. The through holes 424a, 424b and mount pads 426a, 426b are positioned appropriately to lie above and below, and generally or at least particularly in alignment with, the grooves 422a, 422b in the core layer 412. As shown, the core layer 412 may be significantly thicker T than the upper and lower layers 414, 416 to accommodate the thickness of the wires (shown in FIG. 6). Layer thickness may vary, however. It is also expected that multiple layers or sublayers of circuit board material may represent or form one or more of the three illustrated PCB layers 412, 414, 416 as disclosed in the embodiment of FIG. 4 here. Therefore, the invention is not limited by how the layers might be fabricated or how many sublayers make up a noted layer element. For example, FIG. 4A illustrates an alternative embodiment wherein multiple layers or sublayers make up each of the noted layers 412, 414, 416. Layer 412, for example, includes sublayers 412a, 412b, and 412c. Layers 414, 416 include sublayers 414a, 414b, and 416a, 416b, respectively. Greater or lesser numbers of layers or sublayers may make up each of the layer components of the invention.

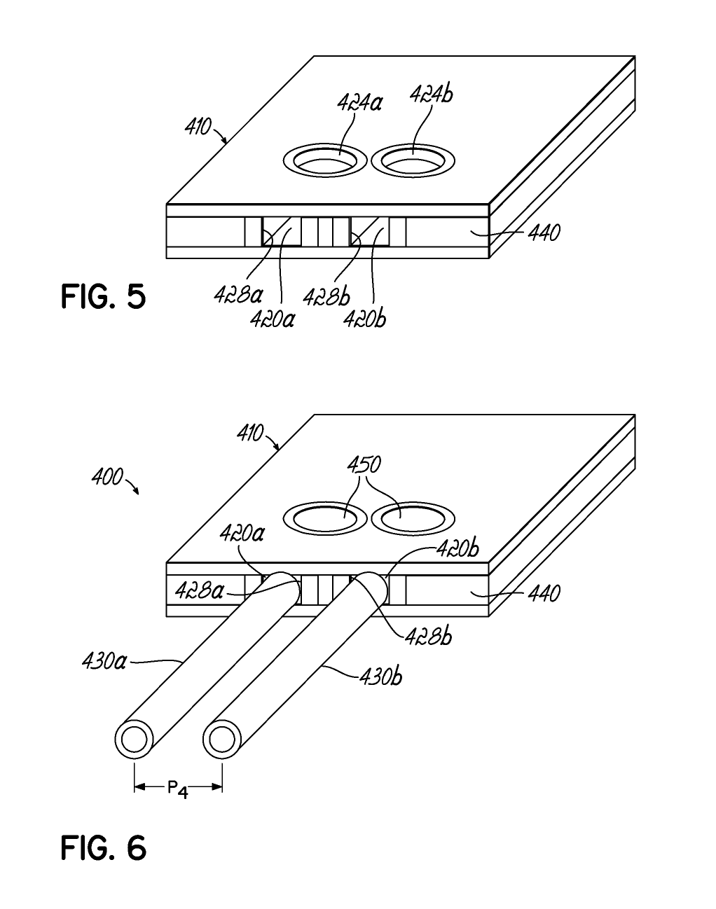

FIG. 5 shows the three layers 412, 414, 416 stacked and coupled together to form a circuit board 410. Sequential lamination may be used to combine the three layers 412, 414, 416. Alternative methods of coupling the layers 412, 414, 416 into a circuit board 410 may also be used. While the board 410 might form the entire board assembly 400, in another embodiment, the three layers making up board 410 might form only part of a larger assembly or a greater stack of layers that comprise the assembly.

In fabricating board 410, the various layers 412, 414, 416 might be appropriately positioned with each other. One layer includes at least one groove 422a, 422b, and another layer including at least one through hole 424a, 424b. The grooves 422a, 422b extend between the face surfaces 443, 445. The layer 414 with the through holes 422a, 422b is coupled with face surface 443 and the layer 416 is coupled with face surface 445. The layers 412, 414 are positioned so that the through holes are in communication with the grooves. Generally, the various layers are positioned together so that appropriate portions thereof cooperate with the grooves to form the cavities 420a, 420b as illustrated in FIG. 5. For example, the layers might be laminated together in sequential lamination steps.

The exemplary completed circuit board 410 as illustrated in FIG. 5 includes two wire cavities 420a, 420b, which are formed from the grooves 422a, 422b in the core layer 412 and the surfaces provided by the upper and lower layers 414, 416. The cavities 420a, 420b have openings at the edge of the board 410 as shown and are sized to receive wires. The cavities are accessed through the front openings 428a, 428b that are formed by the grooves, and the various layers cooperating together. The openings 428a, 428b are defined by the open edges of the grooves 422a, 422b in cooperation with solid edges 444, 446 of the upper and lower layers 414, 416. The openings 428a, 428b are thus, located within or at an edge 440 of the PCB 410 which is formed from the edges 442, 444, 446 of its component layers 412, 414, 416 as shown in FIG. 5.

The cavities 420a and 420b may also be accessed by way of the through holes 424a, 424b. The through holes are particularly constructed for providing access to these cavities once the appropriate wires 430a, 430b and the exposed ends thereof are positioned in the cavities for proper electrical and mechanical connection to the board 410. More specifically, the through holes 424a, 424b provide an opening for solder to flow into the cavities 420a, 420b to secure and electrically connect the wires to board 410, as discussed herein below. To that end, the cavities 420a and 420b might be plated, in whole or in part, with metal to provide a proper electrical connection. In one embodiment, the plating is applied after the lamination of the layers. In another embodiment, some or all of the metal plating is applied to one or more of the layers prior to lamination or coupling the layers together. In yet another embodiment, the plating may be partially or entirely absent, for example in embodiments where solder could be successfully applied within the cavity absent the need for metal plating.

For example, board 410 of the present invention would provide cavities having a certain amount of metal therein based upon the construction of the board. For example, the pads 426a and 426b will be formed of metal, and may actually provide the electrical connection through the circuit board 410 to the wires 430a, 430b. Alternatively, the grooves themselves 422a, 422b might be coated with a suitable metal layer 423, as shown in FIG. 4. In that way, when the core layer 412 and lower layer 416 are coupled together, the formed cavities 420a and 420b will have metal along at least the bottom and sides thereof. The through holes 424a, 424b might also include metallization 425 around their sides, as discussed above. Furthermore, as illustrated the metallization might also extend along a bottom surface 415 of the top layer 414, extending from the through holes 424a, 424b in the direction of, and in alignment with, the grooves, as illustrated in phantom by the metallization patterns 417, as shown in FIG. 8. In that way, upon coupling or laminating together the individual layers 412, 414, 416, the cavities 420a, 420b might be formed, and might be generally completely metalized.

Alternatively, as discussed above, the metal might be applied after the cavities have been formed. In such a case, it may not be necessary to have mount pads 426a, 426b on layer 416 when forming the circuit board. As may be appreciated, the metallization may be on the respective cavity portions of various of the different layers individually, or metallization may be included on all of the layers, as appropriate for a proper electrical connection to be determined by the particular application.

While the illustrated embodiment shows multiple layers coupled together, the board 410 might be formed in another way. The complete board has a first face surface 460 and an opposing or second face surface 462. An edge 440 is positioned or spans between those face surfaces. The closed cavities 420a, 420b are formed in the board and extend into the board from openings 428a, 428b at the edge. The openings at the board edge communicate with the cavity to provide access to the cavity. Through holes are formed in a face surface to also communicate with the cavity.

The exemplary PCB assembly 410 may in some circumstances amount to an additional expense over the construction of typical PCB assemblies such as 110, 210, 310 for the above-disclosed prior art connections 100, 200, 300. However, for some applications, the board already requires multiple layers to be stacked and coupled as illustrated, so that the invention creates little or no additional expense. There are other circumstances where the advantages to this method will justify this particular cost, as further discussed below.

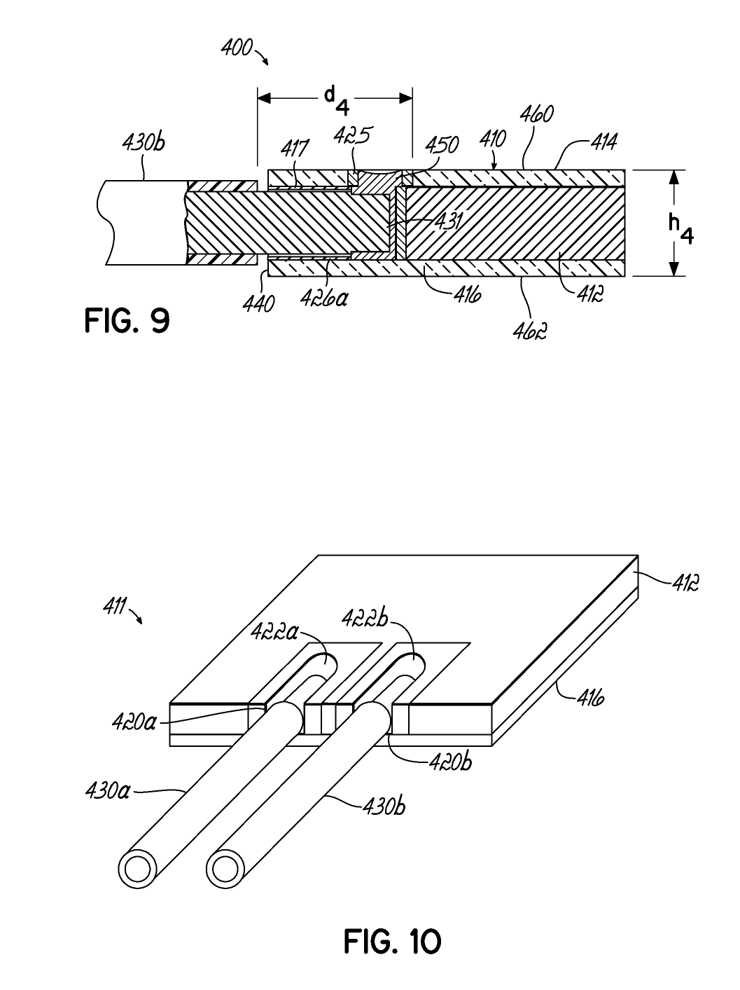

As shown in FIG. 6, the exposed ends of two wires 430a, 430b are inserted into the openings 428a, 428b of the cavities 420a, 420b, and the wire ends are generally coplanar with the plane of the circuit board 410. The wires 430a, 430b are then soldered to the board 410 by applying or flowing solder 450 through the through holes 424a, 424b. Any appropriate solder material may be used, for example an alloy of tin and other metals. Referring now to FIG. 9, the solder 450 that is flowed through the holes 424a, 424b contacts the exposed ends 431 of the wires 430a, 430b. Furthermore, the solder 450 may contact other metal inside the cavities 420a, 420b to further secure the wires and provide a suitable electrical connection between the PCB 410 and the wires and any components coupled thereto. For example, as discussed above, the cavity might include metal surfaces from the mounting pads 426a, 426b as well as any metallization or metal surfaces 423 within the grooves 422a, 422b. Furthermore, metallization on layer 414 and around the through holes 424a, 424b, might include metallization 425 of the through holes as well as metalized tracks 417 that correspond with the various grooves and the defined cavities 420a, 420b, as illustrated in FIG. 8. FIG. 9 shows a cross-sectional view of the flow of solder 450 coupling to various metalized surfaces.

Because solder 450 can be applied into the through holes 424a, 424b relatively little soldering expertise is required to form this connection 400. Because the wires 430a, 430b are inserted parallel to the plane of the circuit board 410, the height of the connection profile is generally no greater than the profile of the board itself.

FIG. 10 illustrates an alternative embodiment 411 of the circuit board of the invention wherein the upper layer 414 has been eliminated. The core layer 412 instead is coupled to the lower layer 416 to form the cavities 420a, 420b in board 411. Since the upper layer is not utilized, the grooves 422a, 422b, and cavities 420a, 420b are directly accessible through the top of the circuit board. The wires 430a, 430b may be laid into their respective grooves and cavities and solder may be flowed directly into the exposed grooves and cavities to provide the robust electrical and mechanical circuit board connection according to aspects of the invention. The various layers may be fabricated as discussed herein

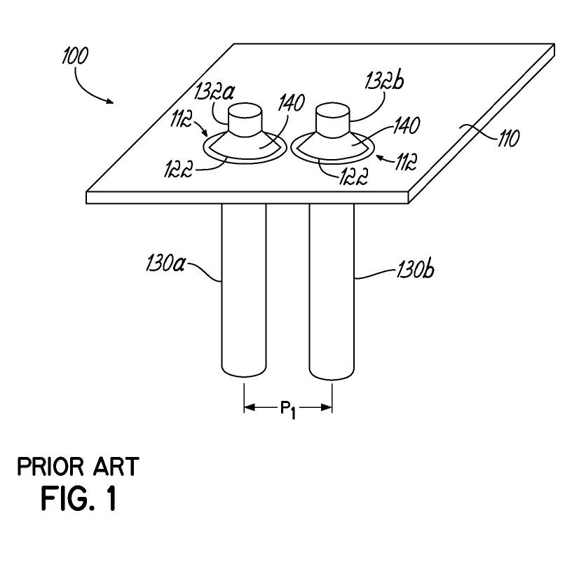

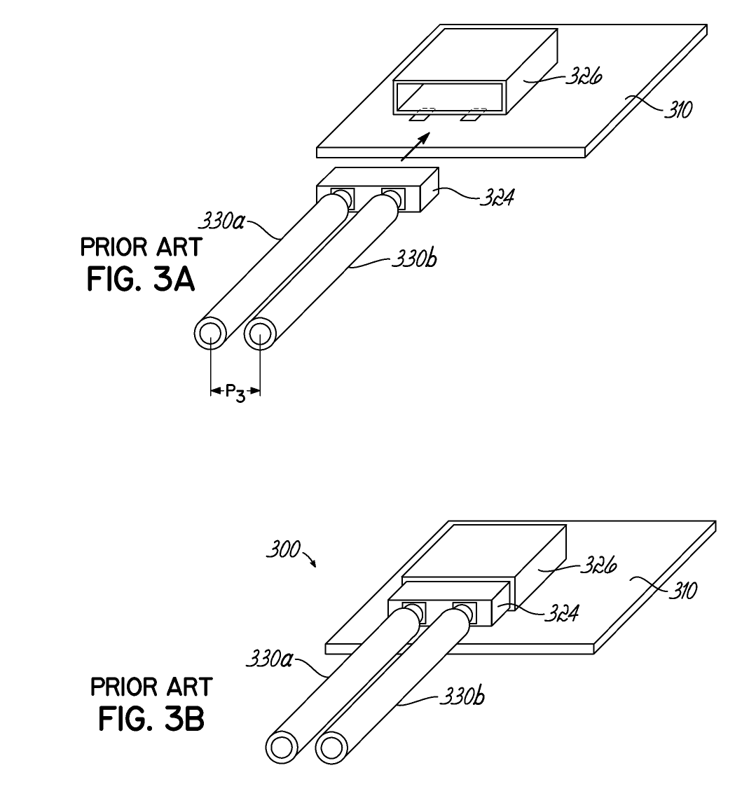

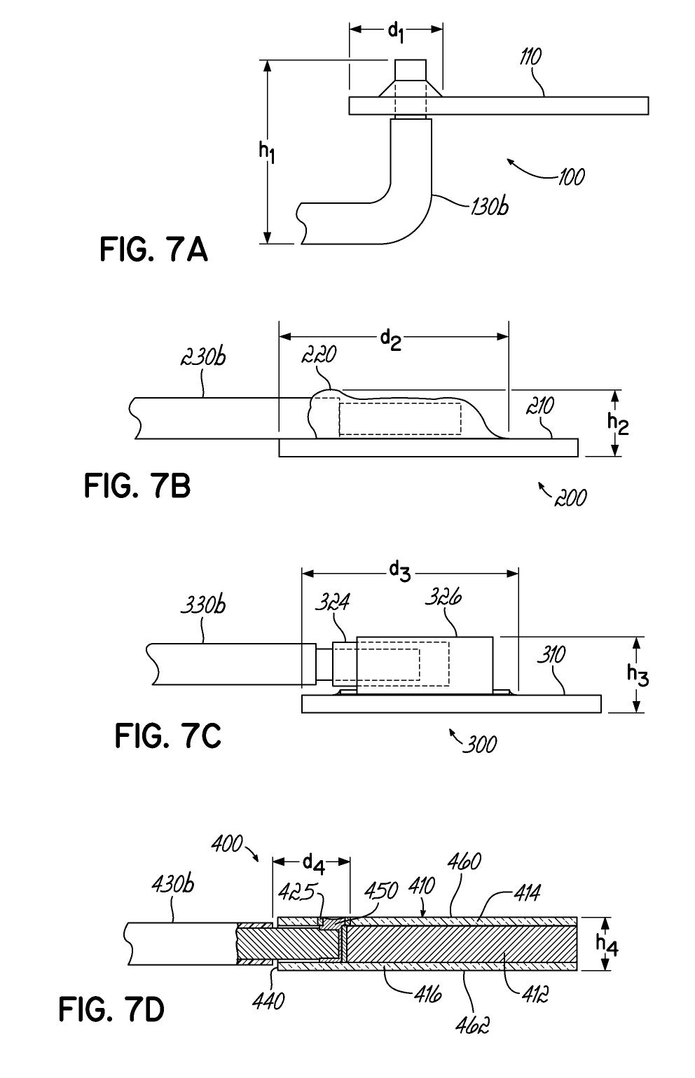

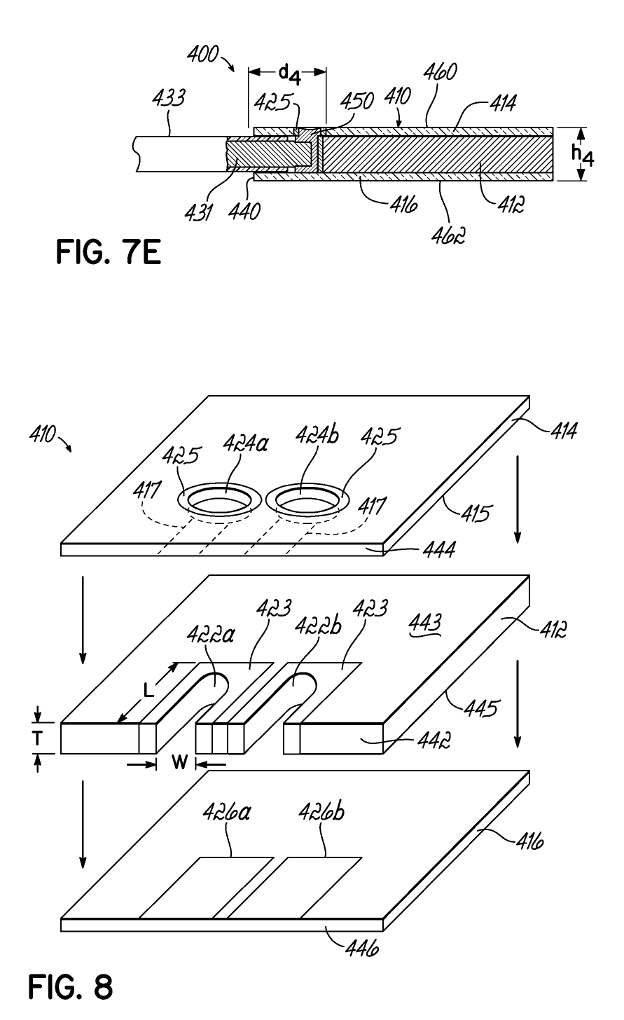

FIGS. 7A-7D show the profiles of the completed wire-to-board connections 100, 200, 300, 400 associated with each of FIGS. 1, 2B, 3B, and 6. An estimated depth d₁-d₄ of each connection into the circuit board and height h₁-h₄ of each profile of the connection and circuit board are shown for purpose of comparison.

In the exemplary connection 400 of the present invention, the required depth d₄ into the circuit board 410 for forming the connection 400 is shown to be less than the required depth d₃ to host the receptacle 326 for a wire-to-board connector 300, and less than the depth d₂ required to apply sufficient encapsulant 220 to the wires 230a, 230b on a surface mount solder 200. The present connection 400 has a similar depth d₄ to the depth d₁ expected of a through hole solder connection 100. In contrast, the height h₄ required for the exemplary connection 400 is far less than the height h₁ required for the perpendicular connection 100 formed for the through hole solder. In fact, as shown, the exemplary connection 400 of the invention has a lower height profile h₄ than any of the other three connections 100, 200, 300. Minimizing the height profile h₄ of the wire-to-board connection 400 is therefore one clear advantage of the present invention.

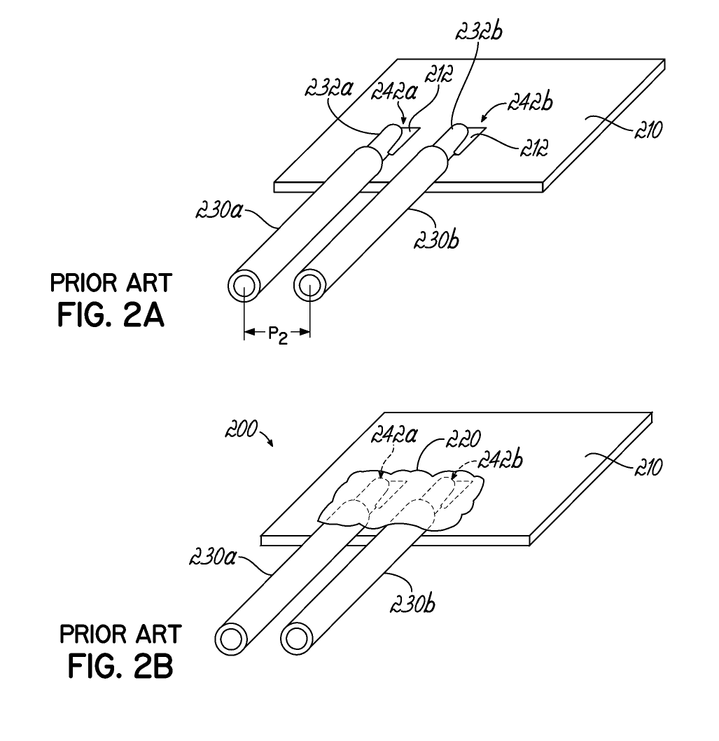

Because the distance between holes is set by the circuit board manufacture, similar to that of the through hole solder connection 100, the pitch P₄ between adjacent wires 430a, 430b in the exemplary connection 400 is also similar to the pitch P₁ of the through hole solder connection 100. As shown, the pitch P₄ is wider than the pitch P₃ of the wire-to-board connector 300. For the wiring scenario of FIGS. 2A and 2B, the wires for surface mount soldering must be placed so that there is sufficient space between them to prevent shorting. Because there is little mechanical control of such wires 230a, 230b to prevent them from moving during the solder operations, the assembly generally requires a wider spacing for wires when using a surface mount solder connection 200. Therefore, the pitch P₄ between adjacent wires 430a, 430b of the exemplary connection 400 is significantly less than the pitch P₂ of the surface mount solder connection 200 as illustrated.

FIG. 7D shows exposed end 431 of wire 430b inserted into the cavity 420b, with insulation 433 outside the cavity. However, as illustrated in FIG. 7E, another embodiment of the invention has a cavity dimensioned to capture part of the insulation adjacent the end of the wire.

The skill required to assemble the exemplary connection 400 is relatively moderate: equivalent to the skill required to solder a through hole connection 100, and less than that required to assemble a wire-to-board connector 300 or a surface mount solder connection 200. The mechanical robustness of the resulting connection 400 is also similar to that of the through hole connection 100, and significantly stronger than that provided by the surface mount solder connection 200 or wire-to-board connector 300.

Although the present connection has many applications, it will be seen that this method of attaching wires to a printed circuit board has particular application to situations where a robust connection is needed with a small height profile, such as in the case of a headphone headset cable.

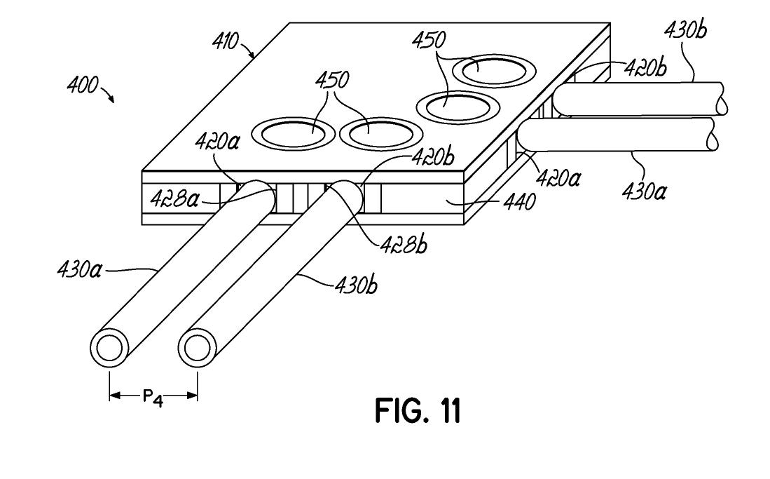

The present invention facilitates a low profile connection to a circuit board that is made proximate the perimeter edge of the board as shown in the figures. The board may be any shape and is not limited to a rectangular shape as illustrated. Also, as illustrated in FIG. 11, the multiple wire connections might be made on a board 410 around its perimeter.

While the present invention has been illustrated by the description of the embodiments thereof, and while the embodiments have been described in considerable detail, it is not the intention of the applicant to restrict or in any way limit the scope of the appended claims to such detail. Additional advantages and modifications will readily appear to those skilled in the art. Therefore, the invention in its broader aspects is not limited to the specific details representative apparatus and method, and illustrative examples shown and described. Accordingly, departures may be made from such details without departure from the spirit or scope of applicant's general inventive concept.

What is claimed is:

1. A circuit board, comprising:
a first layer including a groove formed therein, the groove extending from an edge of the layer and between opposing face surfaces;
a second layer coupled with one face surface of the first layer, the second layer including a through hole in communication with the groove of the first layer;
a third layer coupled to other face surface of the first layer opposite the second layer;
portions of the second and third layers cooperating with the groove and forming a cavity with an opening at an edge of the board, the cavity being accessible through the through hole.

2. The circuit board of claim 1 wherein the first, second, and third layers are coupled together through sequential lamination.

3. The circuit board of claim 1 wherein the cavity formed by the layers includes a metal lining therein.

4. The circuit board of claim 1 wherein the through hole is lined with metal.

5. The circuit board of claim 1 wherein the groove has at least a portion thereof lined with metal.

6. The circuit board of claim 1 wherein the cavity extends generally in a plane defined by the circuit board.

7. The circuit board of claim 1 further comprising a mounting pad positioned on the third layer, the mounting pad being at least partially in alignment with the groove to form part of the cavity.

8. The circuit board of claim 1 wherein at least one of the first, second or third layer includes multiple sub-layers that make up the layer.

9. The circuit board of claim 1 further comprising a plurality of grooves and through holes for forming a plurality of cavities in the board.

10. The circuit board of claim 9 wherein the board defines multiple edges, the plurality of cavities including cavities formed at multiple board edges.

11. A circuit board, comprising:
a first face surface;
a second face surface;
an edge of the board positioned between the first and second face surfaces;
a closed cavity formed in the board and extending into the board from the edge;
an opening into the cavity positioned at the board edge communicating for accessing the cavity;
a through hole, formed in at least one face surface of the circuit board, in communication with the cavity.

12. The circuit board of claim 11 wherein the cavity includes a metal lining therein.

13. The circuit board of claim 11 wherein the through hole is lined with metal.

14. The circuit board of claim 11 wherein the through hole extends generally perpendicular to the extension of the cavity in the printed circuit board.

15. The circuit board of claim 11 wherein the cavity extends generally in a plane defined by the circuit board.

16. The circuit board of claim 11 wherein the board is made up of multiple layers.

17. The circuit board of claim 11 further comprising a plurality of cavities and through holes in the board.

18. The circuit board of claim 17 wherein the board defines multiple edges, the plurality of cavities including cavities formed at multiple board edges.

19. A method of fabricating a circuit board comprising:
positioning a first layer, the first layer including a groove formed therein, the groove extending from an edge of the layer and between opposing face surfaces of the first layer;
coupling a second layer with one face surface of the first layer, the second layer including a through hole formed therein;
positioning the second layer so that the through hole is in communication with the groove of the first layer;
coupling a third layer to the other face surface of the first layer opposite the second layer to form the circuit board;
positioning portions of the second and third layers to cooperate with the groove and form a cavity with an opening at an edge of the board, the cavity being accessible through the through hole.

20. The method of claim 19 further comprising laminating the first, second, and third layers together through sequential lamination to couple the layers.

21. The method of claim 19 further comprising lining the cavity formed by the layers with a metal lining.

22. The method of claim 21 wherein lining the wire cavity with metal lining comprises
electroplating metal onto an inner surface of the wire cavity.

23. The method of claim 19 further comprising lining the through hole with metal.

24. The method of claim 19 further comprising lining at least a portion of the groove in the first layer with metal before coupling the first layer with the second and third layers.

25. The method of claim 19 wherein at least one of the first, second or third layer includes multiple sub-layers that make up the layer.

26. The method of claim 19 further wherein the first layer includes a plurality of grooves and through holes for forming a plurality of cavities in the board.

27. The method of claim 26 wherein the board defines multiple edges, the method further comprising forming the plurality of cavities at multiple board edges.

28. A method of fabricating a circuit board comprising:
forming a closed cavity in a circuit board having a first face surface, a second face surface and an edge of the board positioned between the first and second face surfaces;
extending the cavity into the board from the edge;
positioning an opening into the cavity at the board edge for accessing the cavity;
forming a through hole in at least one face surface of the circuit board and positioning the through hole for communication with the cavity.

29. The method claim 28 further comprising lining the cavity with a metal lining.

30. The method claim 28 further comprising lining the through hole with metal.

31. The method claim 28 further comprising extending the through hole generally perpendicular to the extension of the cavity in the printed circuit board.

32. The method claim 28 wherein the board is made up of multiple layers.

33. The method claim 28 further comprising forming a plurality of cavities and through holes in the board.

34. The method of claim 33 wherein the board defines multiple edges, and further comprising forming the plurality of cavities including cavities at multiple board edges.

35. A circuit board, comprising:
a first layer including a groove formed therein, the groove extending from an edge of the layer and between opposing face surfaces;
a second layer coupled with one face surface of the first layer to cover the groove on one side;
the first and second layers cooperating and forming a cavity with an opening at an edge of the board for receiving wires for securing to the circuit board.

36. The circuit board of claim 35 wherein the first and second layers are coupled together through sequential lamination.

37. The circuit board of claim 35 wherein the cavity formed by the layers includes a metal lining therein.

38. The circuit board of claim 35 wherein the groove has at least a portion thereof lined with metal.

39. The circuit board of claim 35 wherein the cavity extends generally in a plane defined by the circuit board.

40. The circuit board of claim 35 further comprising a mounting pad positioned on the second layer, the mounting pad being at least partially in alignment with the groove to form part of the cavity.

41. The circuit board of claim 35 wherein at least one of the first or second layer includes multiple sub-layers that make up the layer.

42. The circuit board of claim 35 further comprising a plurality of grooves for forming a plurality of cavities in the board.

43. A method of connecting a wire to a circuit board, the method comprising:
providing a first circuit board layer having opposing face surfaces, the first layer including a groove therein;
coupling at least one additional circuit board layer with at a face surface of the first layer to cover the groove for forming a cavity;
inserting the end of a wire into the closed cavity;
administering solder into the cavity to contact the end of the wire.

44. The method of claim 43 wherein the at least one additional layer includes a through hole therein and further comprising positioning the at least one additional layer such that the through hole is in communication with the groove of the first layer.

45. The method of claim 43 further comprising inserting the end of a wire into the closed cavity so that the end of the wire is positioned substantially within the plane of the first layer.

46. The method of claim 43 wherein at least a portion of the wire cavity includes a metal lining, and further comprising soldering the wire to the metal cavity lining.
